(19) United States
(12) Patent Application Publication
(10) Pub. No.: US 2026/0164874 A1
(43) Pub. Date: Jun. 11, 2026

(54) METHOD FOR MANUFACTURING AN OPTOELECTRONIC DEVICE COMPRISING A DIODE COVERED BY AN OPTICAL COMPONENT

(71) Applicant: COMMISSARIAT A L'ENERGIE ATOMIQUE ET AUX ENERGIES ALTERNATIVES, Paris (FR)

(72) Inventors: Quentin ABADIE, Grenoble cedex 09 (FR); Carole PERNEL, Grenoble cedex 09 (FR); Nicolas MICHIT, Grenoble cedex 09 (FR); Margaux AUDIBERT, Grenoble cedex 09 (FR); Valentin VIVARES, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 19/408,641

(22) Filed: Dec. 4, 2025

(30) Foreign Application Priority Data
Dec. 6, 2024 (FR) FR2413597

(51) Int. Cl. H10H 29/01; H10F 71/00; H10F 77/40; H10H 29/855

(52) U.S. Cl. CPC H10H 29/0363; H10F 71/134; H10F 77/413; H10H 29/855

(57) ABSTRACT

The invention relates to a method for manufacturing an optoelectronic device comprising at least one light-emitting or light-receiving diode having a front face intended to transmit or receive light radiation; at least one optical component for shaping the light radiation, located on the front face and covering the diode, and having a lateral variation of a predefined refractive index. The method comprises the following steps: providing the diode; determining a lateral variation in the porosity rate, based on a lateral variation of a predefined target refractive index, a semiconductor portion made of a crystalline material transparent to light radiation and located on the front face and covering the diode; making the semiconductor portion to be porosified; performing an electrochemical porosification of the semiconductor portion, such that it has the determined lateral variation in porosity, the thus porosified semiconductor portion then forming the optical component.

### TECHNICAL FIELD

The field of the invention is that of optoelectronic devices comprising an array of diodes, which are covered by optical components such as microlenses.

### PRIOR ART

The optoelectronic devices can be formed by an array of diodes, for example light-emitting diodes made from a semiconductor material such as a III-V compound, for example GaN, wherein each diode is covered by a microlens intended to improve light extraction and shape the emitted light beam.

The production of microlenses generally comprises a step of structuring a photosensitive resin by photolithography, followed by a creep step, and finally transfer by etching into an organic or inorganic transparent material, for example GaN. These microlenses are usually hemispherical and centrosymmetric.

However, such a method has a number of limitations. Thus, it is relatively complex, due in particular to creep and shape transfer steps in the transparent material. In addition, it offers few degrees of freedom in the sizing of microlenses, which limits the choice of optical properties for shaping the light beam. Furthermore, the microlenses have a curved front face, which can complicate the integration of additional elements, optical or otherwise, above the microlenses.

### DISCLOSURE OF THE INVENTION

The object of the invention is to address, at least partially, the disadvantages of the prior art. For this purpose, the invention relates to a method for manufacturing an optoelectronic device comprising at least one diode, a light-emitting or light-receiving diode, covered by an optical component having a lateral variation in the refractive index obtained by electrochemical porosification.

More specifically, the object of the invention is a method for manufacturing an optoelectronic device comprising: at least one light-emitting or light-receiving diode having a front face intended to transmit or receive light radiation; at least one optical component for shaping the light radiation, located on the front face and covering the diode, and having a lateral variation in the predefined refractive index.

The manufacturing method comprises the following steps: providing the diode; determining a lateral variation in the porosity rate, based on a predefined lateral variation in a predefined target refractive index, a semiconductor portion made of a crystalline material that is transparent to light radiation and located on the front face and covering the diode; producing the semiconductor portion to be porosified; performing electrochemical porosification of the semiconductor portion, such that it exhibits the determined lateral variation in porosity rate, the semiconductor portion thus porosified then forming the optical component.

Some preferred but non-limiting aspects of this manufacturing method are as follows.

The semiconductor portion to be porosified may have a flat upper face opposite the front face of the diode.

During the step of producing the semiconductor portion to be porosified, it may comprise several adjacent doped areas, which may have a different doping level from one doped area to the other.

During the electrochemical porosification step, the doped areas can be porosified and can have a different porosity rate from one doped area to the other.

During the step of producing the semiconductor portion to be porosified, each doped area may have a homogeneous doping level laterally and vertically.

The optoelectronic device may comprise an array of diodes and several optical components formed from semiconductor portions to be porosified. During the step of producing the semiconductor portions to be porosified, these may be parts of the same continuous semiconductor layer that can extend over the array of diodes.

During the electrochemical porosification step, an electrical anodization signal may have a constant value over time until the lateral variation in the porosity rate is obtained.

During the electrochemical porosification step, the intensity of an electrical anodization signal can be modulated, which can lead to lateral variation in the porosity rate.

During the step of producing the semiconductor portion to be porosified, it may have a laterally homogeneous level of doping.

During the step of producing the semiconductor portion to be porosified, it may have a free lateral edge.

During the step of producing the semiconductor portion to be porosified, it may have an upper face covered by a thin protective portion made from a material that cannot be porosified during the electrochemical porosification step.

The semiconductor portion to be porosified may be made of a material based on (Al,In,Ga)N or InP.

The manufacturing method may comprise one or more of the following steps: producing the semiconductor portion to be porosified, in the form of a mesa, from a growth substrate; producing the diode from the semiconductor portion to be porosified; transferring the diode and the semiconductor portion to be porosified onto a control substrate; performing the electrochemical porosification of the semiconductor portion.

The invention also relates to an optoelectronic device, comprising: at least one light-emitting or light-receiving diode having a front face for transmitting or receiving light radiation; at least one optical component for shaping the light radiation, located on the front face and covering the diode, and having a lateral variation of a predefined refractive index, made of a transparent crystalline material, and having a lateral variation in the porosity rate of the transparent crystalline material.

### BRIEF DESCRIPTION OF THE DRAWINGS

Other aspects, aims, advantages and features of the invention will become more apparent upon reading the following detailed description of preferred embodiments thereof, provided by way of non-limiting example, and made with reference to the appended drawings wherein:

FIGS. 1A and 1B are schematic and partial cross-sectional view (FIG. 1A) and top view (FIG. 1B) of an optoelectronic device according to a first embodiment, wherein the optical components are obtained by electrochemical porosification of semiconductor portions having a lateral variation in the doping level;

FIG. 2 is a schematic and partial cross-sectional view of an optoelectronic device according to a second embodiment, wherein the optical components are obtained by electrochemical porosification with modulation of the anodizing voltage Eₐ;

FIGS. 3A to 3F illustrate various steps of a method for manufacturing an optoelectronic device similar to that of FIG. 1A;

FIGS. 4A to 4C illustrate various steps of a method for manufacturing an optoelectronic device similar to that of FIG. 1A.

FIGS. 5A to 5C illustrate various steps of a method for manufacturing an optoelectronic device similar to that of FIG. 2;

FIGS. 6A to 6D illustrate various steps of a method for manufacturing an optoelectronic device similar to that of FIG. 2.

FIGS. 7A and 7B are schematic and partial views, in cross-section (FIG. 7A) and in top view (FIG. 7B), of an optoelectronic device according to a variant of the first embodiment.

FIG. 8 is a schematic, partial, cross-sectional view of an optoelectronic device 1 according to another variant of the first embodiment.

### DETAILED DISCLOSURE OF PARTICULAR EMBODIMENTS

In the Figures and in the following description, the same reference signs represent identical or similar elements. In addition, the different elements are not represented to scale, so as to improve the clarity of the Figures. Moreover, the different embodiments and alternatives are not mutually exclusive and could be combined together. Unless stated otherwise, the terms “substantially”, “about”, and “in the order of” mean within a 10% margin, and preferably within a 5% margin. Moreover, the terms “between . . . and . . . ” and equivalents mean that the bounds are included, unless specified otherwise.

The invention relates to an optoelectronic device, and its manufacturing method, comprising at least one diode, and preferably a diode array, at least one planar optical component, covering at least the diode, adapted to shape the light radiation emitted or received by the diode, this optical component having a lateral variation Δ_{xy}ñ in refractive index ñ obtained by electrochemical porosification. The shaping of the light radiation thus corresponds to a local phase delay applied to the light radiation, induced by this lateral variation Δ_{xy}ñ of the refractive index, such that the emitted light radiation is shaped by refraction. The light radiation may furthermore be subjected to competing physical phenomena as it passes through the planar optical component, such as scattering or diffraction phenomena, which only marginally affect the optical power of the transmitted light radiation, for example by less than 25% of its total power, or less than 10%.

According to the invention, the optical component is produced by electrochemical porosification of a transparent semiconductor portion, where the lateral variation Δ_{xy}p in the porosity rate p(x,y) results in a desired lateral variation Δ_{xy}ñ in the refractive index ñ. The semiconductor portion porosified in this way therefore forms the optical component.

The porosity rate p(x,y) (or porosification rate) is defined here as the ratio between the volume of the pores (void volume) and the considered volume of the optical component, this considered volume intercepting at least 5 pores, and preferably at least 10 pores. It has a local value measured in the optical component, which can vary between a minimum value (0 when it does not comprise pores: no porosification) and a maximum value (1 when it is fully porous).

The porosity rate p(x,y) varies laterally in a discrete (stepwise) or continuous manner. Δ_{xy}p is the lateral variation in the XY plane, i.e. in a plane parallel to the front face of the diode(s). It may have one extremum located on the central axis of the optical component (which may be coaxial with the optical axis of the underlying diode) and one extremum located at the lateral edge. It can also have different values for adjacent areas, similar to a QR code. These various examples are described in the following with reference to the Figures.

The lateral variation of a quantity may be described as the deviation of this quantity in the XY plane relative to a reference value, for example equal to the average of this quantity in that plane. Its amplitude, expressed as a percentage, is defined as the difference between its opposite extrema, relative to this reference value.

Similarly, a thickness variation of a quantity is defined. This variation may be described as the deviation taken by this quantity along a direction orthogonal to the XY plane relative to a reference value, for example equal to the average of this quantity along this direction at the considered point of the XY plane. Its amplitude, expressed as a percentage, is defined as the difference between its opposite extrema along this direction, relative to this reference value.

Preferably, the porosity rate p(x,y) is constant according to the thickness of the optical component. The porosity rate p(x,y) may exhibit a residual thickness variation induced by the manufacturing method. If present, its amplitude is typically less than or equal to 4% in absolute value, at all points (x, y). In other words, the porosity rate p(x,y) preferably varies only laterally and not also vertically, so that it can be denoted as p(x,y). However, alternatively, a vertical variation Δ_{z}p in the porosity rate p(x, y, z) may also be obtained.

The refractive index ñ(x,y) of the optical component is then an ‘effective’ or ‘average’ refractive index, typically averaged over a volume whose dimensions are on the order of the wavelength of interest, the local value of which depends on that of the porosity rate p(x,y). It is defined as the ratio of the refractive index n₀ of the intact or dense material of the optical component and the porosity rate p(x,y): ñ(x,y)=(1−n₀)×p(x,y)+n₀. To provide a light-shaping function, in particular for the purpose of modifying the divergence, the convergence and/or the direction of a light radiation, it is generally accepted that the amplitudes of the necessary lateral variations of the porosity rate p(x,y) and of the effective refractive index ñ(x,y) are typically greater than or equal to 5%.

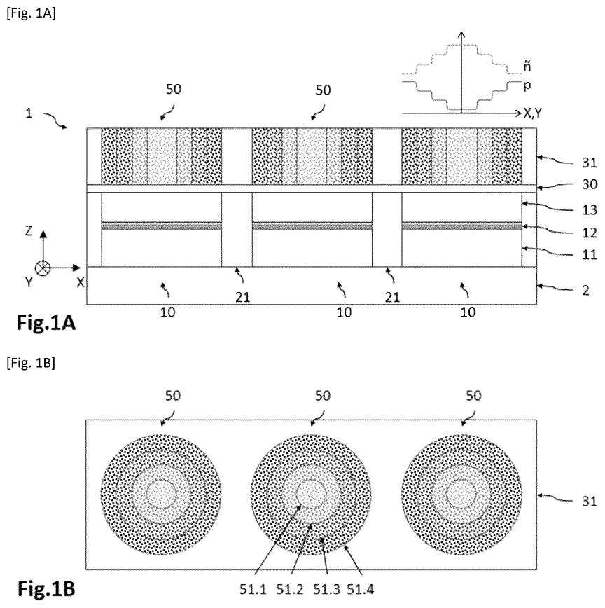

FIGS. 1A and 1B are schematic and partial views, in cross-section (FIG. 1A) and in top view (FIG. 1B), of an optoelectronic device 1 according to a first embodiment;

In general, the diodes can be light-emitting diodes such that the optoelectronic device 1 can be, for example, a display screen or a lighting system. They can thus be organic (OLED) or inorganic (LED) light-emitting diodes. Alternatively, the diodes can be detecting diodes, such that the optoelectronic device can be a matrix-array photodetector. This can involve organic or inorganic photodetectors. In this example, the diodes D are light-emitting diodes.

Here and in the rest of the description, a direct three-dimensional orthogonal XYZ coordinate system is used, where the X and Y axes form a main plane in which the diode array 10 extends, and where the Z axis is oriented along the thickness of the diode array 10 towards the optical components 50. The terms ‘lower’ and ‘upper’ are defined relative to a positioning increasing along the +Z direction.

The optoelectronic device 1 comprises a control substrate 2, an array of light-emitting diodes 10, and optical components 50 that cover the diodes 10, each optical component 50 here being planar and with lateral variation Δ_{xy}ñ in the refractive index ñ obtained by electrochemical porosification.

The control substrate 2 comprises a CMOS-type control circuit (not shown), and has electrical connection pads (not shown) that are flush with the upper face and come into contact with lower conductive portions of the diodes 10. These lower conductive portions are separate from one another, in the sense that each diode 10 is electrically separate from the adjacent diode, and can be polarized independently of its neighbors. This configuration is described in detail in document WO 2017/194845 A1. Other configurations are possible.

Here, the diodes D are inorganic light-emitting diodes. They can be produced in a conventional manner, for example by epitaxy of semiconductor layers starting from a growth substrate, then transferred to the control substrate 10. Each diode 10 may be formed of a stack consisting of: a lower semiconductor portion 11 (located on the side of the control substrate 2) doped with a first type of conductivity, for example P-type; an active area 12 where the light radiation of the light-emitting diode is emitted; and an upper semiconductor portion 13 doped with a second type of conductivity, for example of the N-type. The diodes 10 may be made from the same semiconductor compound, for example based on a III-V compound, such as for example InP, and preferably based on an III-N compound such as GaN, InGaN, or AlGaN.

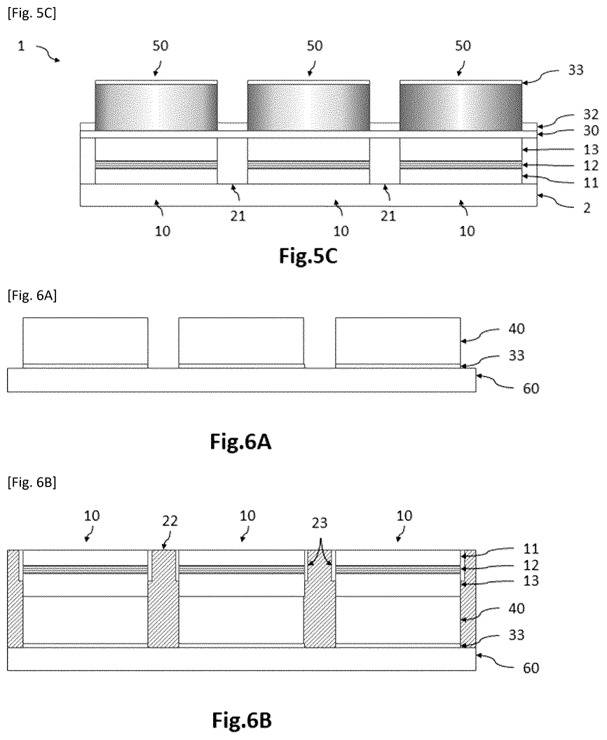

In this example, the diodes are structurally identical, so that the emitted light radiation is identical from one diode to another in terms of wavelength. Here, the diodes can be adapted to emit blue light radiation, i.e. light for which the emission spectrum has an intensity peak at a wavelength between about 440 nm and 490 nm. Alternatively (as described with reference to FIG. 6A et seq.), the diodes may emit at different wavelengths. The diodes are here separated in pairs in the XY plane, and the space between the diodes may be filled with an electrically insulating filling material 21 that comes into contact with the lateral edge of portions 11, 12 and 13.

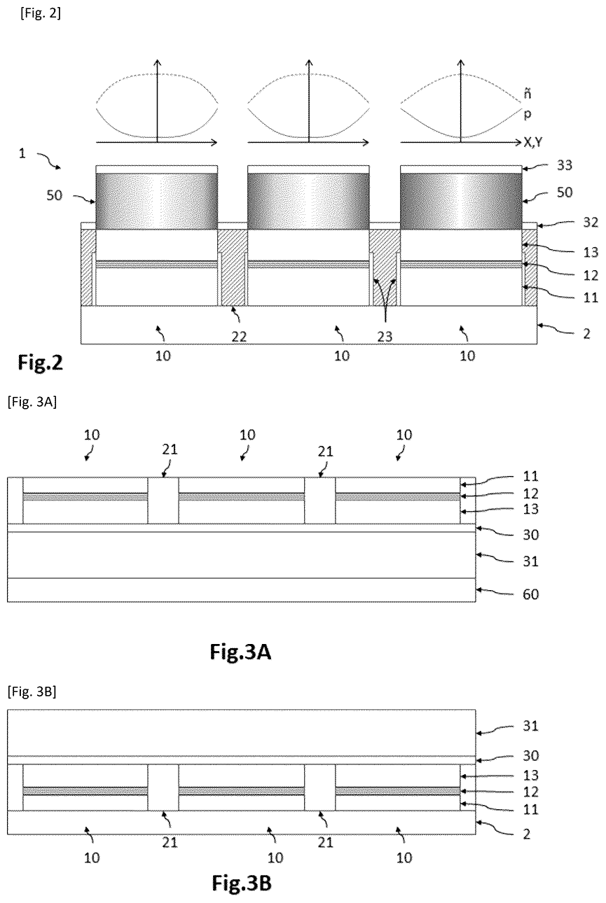

The diodes 10 are electrically polarized by the control substrate 2. Thus, the P-doped portions 11 are in electrical contact with underlying conductive pads (not shown). Furthermore, the N-doped portions 13 may be polarized in different ways. FIG. 1A illustrates an example where they are polarized by means of a thin transparent conductive layer 30, which extends above the diodes 10 and below the optical components 50, here made from an N-doped semiconductor III-V compound. This polarizing thin conductive layer 30 can be connected to the control substrate 2 by one or more conductive vias (not shown) located between the diodes 10, or located at the lateral edge of the diode array 10. FIG. 2 illustrates another example where the N-doped portions 13 are polarized laterally by a conductive material 22, located in the interdiode space, which comes into contact with the lateral edge of the N-doped portions 13. A thin insulating layer 23 is located between this conductive material 22 and the lateral edge of the active areas 12 and the P-doped portions 11. Other examples of polarization are possible.

The optoelectronic device comprises planar optical components with lateral variation in refractive index ñ(x,y), which each cover at least one underlying diode. In this example, each diode is covered by an optical component.

The optical component 50 here has dimensions of length and width in the XY plane that are substantially equal to those of the underlying diode 10. Alternatively, the dimensions of the optical component 50 may be larger or smaller than those of the diode 10.

The optical component 50 is here planar insofar as it has a flat upper face, opposite the front face of the diodes 10. It is preferably parallel to the front face, and preferably the upper faces of the optical components 50 are coplanar. They are therefore all the same thickness here, making it easier to integrate additional elements.

The optical component 50 is formed from at least one semiconductor material that is transparent in the emission or detection spectral band of the diodes 10. This is a crystalline material that has been made porous by electrochemical anodization. It may be a nitride compound of the (Al,In,Ga)N type, i.e. an AlₓIn_{y}Ga_{z}N component, where x+y+z=1 with 0≤x≤1, 0≤y≤1 and 0≤z≤1. Preferably, x is less than or equal to 0.75, or even less than or equal to 0.5. It can also be InP. It should be noted that the thin conductive polarization layer 30 can be formed from a similar material, for example in an AlₓIn_{y}Ga_{z} N-type compound, N-doped. It has a sufficient level of doping N_{D} to allow electrical polarization of the N-doped portions 13, but insufficient to undergo electrochemical porosification. For this purpose, doping with germanium atoms is preferred. The concentration of germanium atoms may be less than or equal to 1E22 at/cm³, preferably less than or equal to 1E21 at/cm³. For doping with silicon atoms, the concentration of silicon atoms may be less than or equal to 1.5E19 at/cm³. The thin conductive layer 30 is more conductive the higher the doping level N_{D}.

Each optical component 50 has a lateral variation Δ_{xy}ñ in refractive index ñ. As defined previously, the refractive index ñ is an ‘effective’ refractive index which is defined by the relationship ñ(x,y)=(1−n₀)×p(x,y)+n₀. The refractive index n₀ has a constant value in the spectral range of diode emission or detection. In the case of GaN, the refractive index n₀ is approximately 2.4.

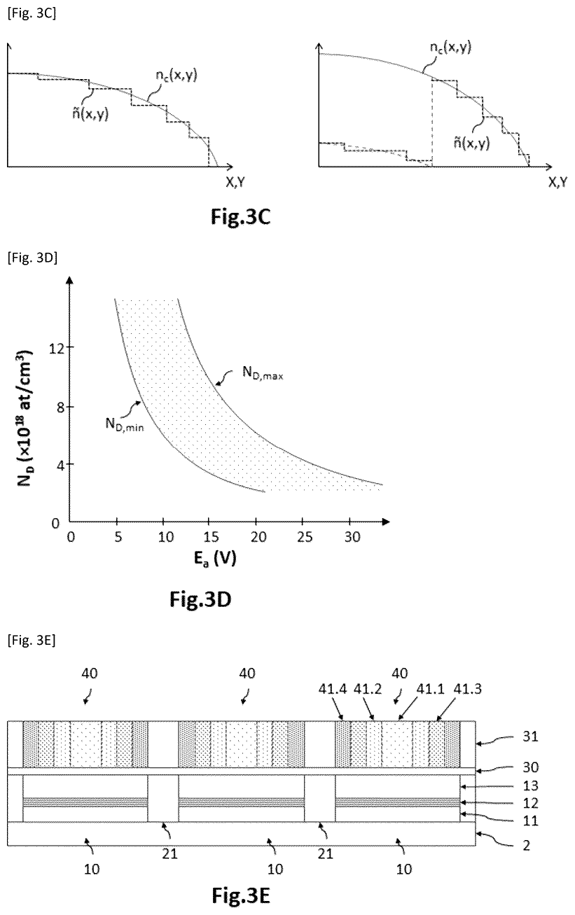

In the example of FIG. 1A, the lateral variation Δ_{xy}p in the porosity rate p(x,y) was obtained by localized electrochemical porosification of transparent semiconductor portions 40 (see FIG. 3F), here parts of the same continuous semiconductor layer 31. Each semiconductor portion 40 had a lateral variation Δ_{xy}N_{D} of the doping level N_{D}, which is reflected by a lateral variation Δ_{xy}p in the porosity rate p, and therefore by the desired lateral variation Δ_{xy}ñ in the refractive index ñ. The steps of the manufacturing process are detailed below with reference to FIG. 3A et seq.

The porosity rate p(x,y) varies in the XY plane in a discrete manner, and has concentric areas 51.1, 51.2, 51.3, 51.4, centered on a central optical axis of the diode 10 and of the optical component 50, within which it has a substantially constant value. They extend over substantially the entire thickness of the optical component 50. In this example, four concentric areas are represented, but the optical component 50 may have a larger, or smaller, number of areas, which may be arranged in different ways and have different dimensions in the XY plane. Here, these concentric areas are formed from a central area 51.1, which here has a minimum porosity rate p and therefore a maximum refractive index ñ, then from a succession of annular areas 51.2, 51.3, 51.4 which extend from the central area 51.1 to the lateral edge of the optical component 50, where the porosity rate p increases from one area to the other and therefore where the refractive index ñ decreases accordingly.

The optical components 50 are here parts of the same semiconductor layer 31, which extends continuously over the diode array 10, being here in contact with the thin conductive polarization layer 30. The portions of the continuous semiconductor layer 31, located between the optical components 50, are here not porosified, but they could be.

Thus, by means of the optical components 50 whose lateral variation Δ_{xy}p in the porosity rate p, and therefore the lateral variation Δ_{xy}ñ in the refractive index ñ, is obtained by electrochemical porosification, it is possible to avoid the constraints presented by the manufacturing methods of the microlenses described previously with reference to the prior art, and in particular the limitations associated with the creep and shape transfer steps in the transparent material. In addition, such optical components 50 have many degrees of freedom in terms of manufacturing, making it possible to adjust, according to the intended applications, their optical properties for shaping the transmitted light beam. These degrees of freedom are in particular the choice of lateral variation Δ_{xy}N_{D} of the doping level N_{D} in the semiconductor portions 40 to be porosified and/or the choice of operating conditions during the electrochemical porosification step, in particular the value or modulation of the anodizing voltage Eₐ. Moreover, the optical components 50 are preferably planar, thus facilitating the integration of additional elements, optical or not, after the optical components have been produced.

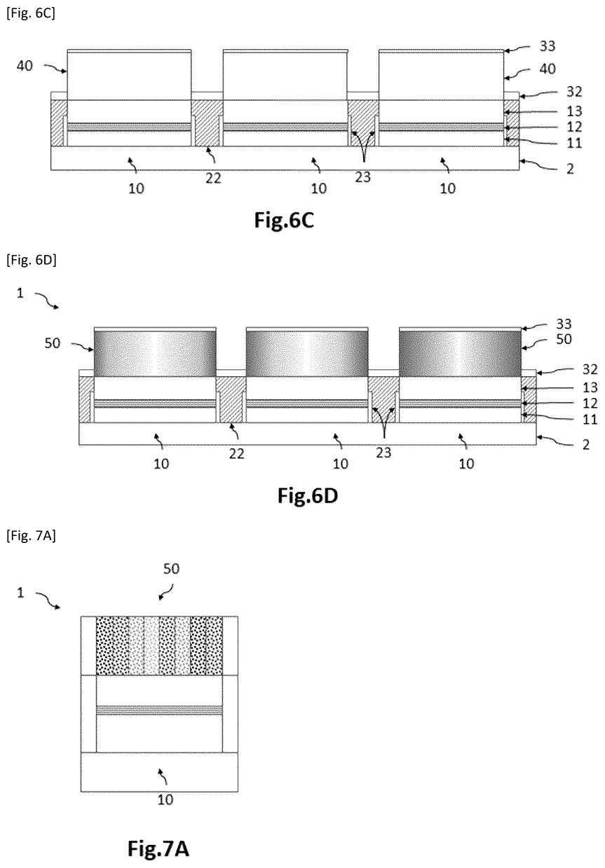

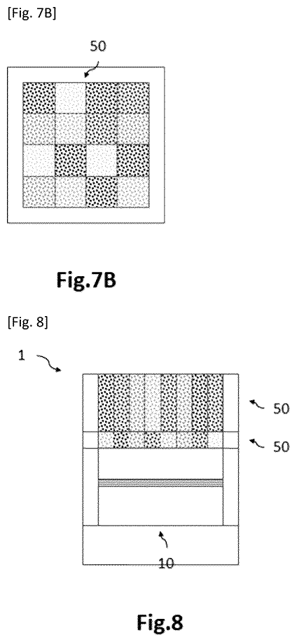

The optical components 50 may form convergent or divergent microlenses, with an optical axis which may be coaxial (or not) with the optical axis of the diode. As described below with reference to FIGS. 7A, 7B and 8, the optical components 50 can form metasurfaces (“QR-code” type).

The optical components 50 may be intended to transmit the light beam in free space. They may also be coupled to an optical guide, for example an optical fiber, in particular in the context of a telecommunications or data communications application.

It should also be noted that the porosity of the optical components 50 makes it possible to incorporate a material (colored resin) or color conversion semiconductor elements, such as quantum dots. If present, the formula linking the porosity rate to the effective refractive index takes into account the replacement of air or vacuum with the incorporated material, so that ñ(x,y) equals (nₘ−n₀)×p(x,y)+n₀, where nₘ is the refractive index of the incorporated material.

FIG. 2 is a schematic, partial, cross-sectional view of an optoelectronic device 1 according to a second embodiment. The optoelectronic device 1 differs from that of FIG. 1A essentially in that the optical components 50 have a continuous, and not discrete, lateral variation Δ_{xy}p in the porosity rate p and therefore in the refractive index ñ.

The optical components 50 are herein separate from each other in the XY plane, and are not part of the same continuous semiconductor layer in the same material. Each optical component 50 therefore has, in the XY plane, a free (uncovered) lateral edge, through which the electrochemical porosification has been performed.

The porosity rate p varies in the XY plane continuously, hence also the refractive index ñ. In this example, the porosity rate p has a maximum value at the lateral edge of the optical components 50 and a minimum value at the center. The lateral gradient here differs from one optical component to another. Note that other lateral variations are entirely possible.

In order to obtain an essentially lateral rather than vertical variation in the porosity rate p and therefore in the refractive index ñ, each optical component 50 comprises a thin protective layer 33, which extends over the upper face. It can be made of silicon oxide. It is preferably made of a material similar to that of the optical components 50, i.e. here made of AlₓIn_{y}Ga_{z}N or InP, but is not doped or only slightly doped so that it has not been porosified during the electrochemical porosification step.

Here, the N-doped portions 13 are laterally polarized by a conductive material 22, for example a metallic material such as copper, located in the interdiode space. As indicated previously, a thin lateral layer 23, made of an electrically insulating material, extends over the lateral edge of the active area 12 and the P-doped portion 11, to insulate them from the conductive material 22. So as not to damage this conductive material 22 during the electrochemical porosification step, a thin protective layer 32 extends between the optical components 50 and covers the conductive material 22 in the interdiode space. This thin protective layer 32 prevents the liquid electrolyte from coming into contact with the conductive material 22.

FIGS. 3A to 3F illustrate various steps of a method for manufacturing an optoelectronic device similar to that of FIG. 1A. Here, the lateral variation Δ_{xy}p in the porosity rate p is obtained by previously performing a lateral variation Δ_{xy}N_{D} of the doping level N_{D} in the semiconductor portions 40. Moreover, the step of pixelating the diodes 10 is carried out before the step of transferring onto the control substrate 2.

With reference to FIG. 3A, a diode array 10 is produced from a growth substrate 60. The growth substrate 60 may be a thick substrate (wafer) for example made of silicon, sapphire or other material, covered for example with a nucleation layer (not shown). The continuous semiconductor layer 31 is then produced by epitaxy from the nucleation layer. In this example, it may be produced from non-doped or slightly doped N-type GaN, for example unintentionally doped. This continuous semiconductor layer 31 is intended to form the semiconductor portions 40 and therefore subsequently the optical components 50.

The continuous semiconductor layer 31 is covered by a thin conductive layer 30, here made of an N-doped crystalline semiconductor material, for example GaN, by epitaxy from the continuous semiconductor layer 31. The thin conductive layer 30 is intended to ensure the electrical polarization of the N-doped portions 13 of the diodes 10. However, its doping level is chosen to substantially not undergo porosification during the subsequent electrochemical anodization step.

The diodes 10 are produced by epitaxy of an N-doped semiconductor layer, then an active layer which may comprise quantum wells, and a P-doped semiconductor layer. This stack is then pixelated to form the diode array 10. A filling material 21, in this case electrically insulating, fills the space between the diodes.

With reference to FIG. 3B, the stack is transferred onto a control substrate 2, then the growth substrate is removed, so as to expose the upper face of the continuous semiconductor layer 31. The control substrate 2 comprises conductive pads (not shown) located beneath and in electrical contact with the P-doped portions 11, and one or more conductive pads (not shown) in electrical contact with the thin conductive layer 30 for polarization of the N-doped portions 13.

With reference to FIG. 3C, FIG. 3D and FIG. 3E, a lateral variation Δ_{xy}N_{D} in the doping level N_{D} (x,y) is carried out in parts of the continuous semiconductor layer 31, so as to form doped semiconductor portions 40 intended to form, once porosified, the optical components 50. Here, this spatial distribution of the doping level N_{D}(x,y) is carried out by ion implantation. However, in the case where the continuous semiconductor layer 31 had been N-doped during growth, this spatial distribution of the doping level N_{D(x,y)} can be carried out by localized dedoping, as indicated in particular in document WO 2024/134081 A1.

Prior to this, a desired phase profile φ(x,y) of the optical component 50 is determined, corresponding to the phase delay that is intended to be applied to the emitted light radiation. This phase profile depends on the type of optical component desired and its properties for shaping the light beam emitted by the underlying diode 10. A lateral variation Δ_{xy}n_{c} of target refractive index n_{c} (x,y) is deduced from the relationship: n_{c} (x,y)=λ/(2π×h)×φ(x,y), where λ is a central wavelength of the emission spectrum of the diode and where h is the thickness of the semiconductor portion 40 to be porosified. As expressed herein, n_{c}(x,y) corresponds to the refractive index required to apply a phase delay equal to the desired phase profile φ(x,y) to a plane wave passing through the semiconductor portion 40 at normal incidence. This is notably the case when the light radiation is emitted by carrier recombination in quantum wells of the diode 10, and when these quantum wells extend parallel to the lower and upper faces of the semiconductor portion 40. In FIG. 3C, this target variation n_{c} (x,y) is represented as a continuous linear line (without increments).

A discrete lateral variation Δ_{xy}ñ is then determined for the final refractive index ñ(x,y), and therefore for the porosity rate p(x,y), which is adjusted (by curve fitting) to the lateral variation of target refractive index n_{c} (x,y). This variation Δ_{xy}ñ is here discrete, and is represented in FIG. 3C as a dotted line with increments. The corresponding lateral variation Δ_{xy}p in the porosity rate p(x,y) is then deduced: p(x,y)=(ñ(x,y)−n₀)/(1−n₀) . It should be noted, as illustrated by the graph to the right of FIG. 3C, that, if the high values of the target refractive index n_{c} are greater than the index of the intact material, here of GaN (n₀=2.4), it is possible to adapt the lateral variation Δ_{xy}n_{c} of the target refractive index n_{c} (x,y) by a modulation by 2π of the phase profile φ.

FIG. 3D shows an example of the relationship between the doping level N_{D} of a doped crystalline layer as a function of the applied electrical anodizing voltage Eₐ, highlighting the range of electrochemical porosification. Such an example is described in particular in document EP 3,840,016 A1. Below a minimum doping level N_{D,min} and at a low anodizing voltage Eₐ, the process involves the formation of channels rather than porosity. This is referred to as a pre-breakdown. Conversely, above a maximum doping level N_{D,max} max and at high anodizing voltage Eₐ, the process is that of etching by electropolishing the material. Between these two processes is the process of electrochemical porosification. Thus, this type of chart shows the relationship between the level of doping N_{D} required, for a given anodizing voltage Eₐ, and the porosity rate p. Indeed, at a constant doping level, increasing the anodizing voltage Eₐ leads to an increase in the porosity rate p. Similarly, at a constant anodizing voltage Eₐ, increasing the doping level leads to an increase in the porosity rate p. Therefore, knowing the spatial variation Δ_{xy}p that was determined, the corresponding spatial variation Δ_{xy}N_{D} of the doping level is deduced, for a given anodizing voltage Eₐ. The porosity rate may thus vary over a wide range of values, for example from 1% to 70%, or from 5% to 65%.

Finally, as illustrated in FIG. 3E, the spatial distribution Δ_{xy}N_{D} determined in each semiconductor portion 40 is achieved, here by ion implantation. In this example, there are several concentric areas 41.1, 41.2 . . . , centered on the optical axis of each semiconductor portion 40 (coaxial here with that of the underlying diode 10), where the doping level N_{D} is substantially homogeneous in the XY plane and along the direction Z. The semiconductor portions 40 are separated in pairs, and are here separated by an unintentionally doped area.

With reference to FIG. 3F, the optical components 50 are produced by electrochemical porosification of the doped areas 41 of the semiconductor portions 40. For this purpose, the free face of the continuous semiconductor layer 31 (and therefore the semiconductor portions 40) is put in contact with a liquid electrolyte. The liquid electrolyte may be acidic or alkaline, and may be oxalic acid. It may also be HCl, KOH, HF, HNO₃, NaNO₃, H₂SO₄ or a mixture thereof. Thus, a mixture of oxalic acid and NaNO₃ may also be used. The structure is electrically connected to an electrical generator, here for example via the thin conductive layer 30 which makes it possible to polarize the semiconductor portions 41 to be porosified. The thin conductive layer 30 then forms a working electrode, here connected to the anode of the electric generator. A counter electrode (here a platinum grid) is immersed in the electrolyte and connected to the cathode of the electric generator. The electric generator applies an anodizing voltage Eₐ. Thus, the doped areas 41 of the different semiconductor portions 40 are porosified, each according to the doping level, resulting in a porosity rate p specific to each doped area. The semiconductor portions 40 then porosified therefore have the desired lateral variation Δ_{xy}p in the porosity rate p(x,y), and therefore the lateral variation in refractive index ñ(x,y), thus forming the optical components 50. The amplitude of the desired lateral variation Δ_{xy}p is typically greater than or equal to 5%, or even greater than or equal to 10%, this value depending in particular on the thickness h, on the nature of the material of the semiconductor portion 40, and on desired phase profile φ(x,y).

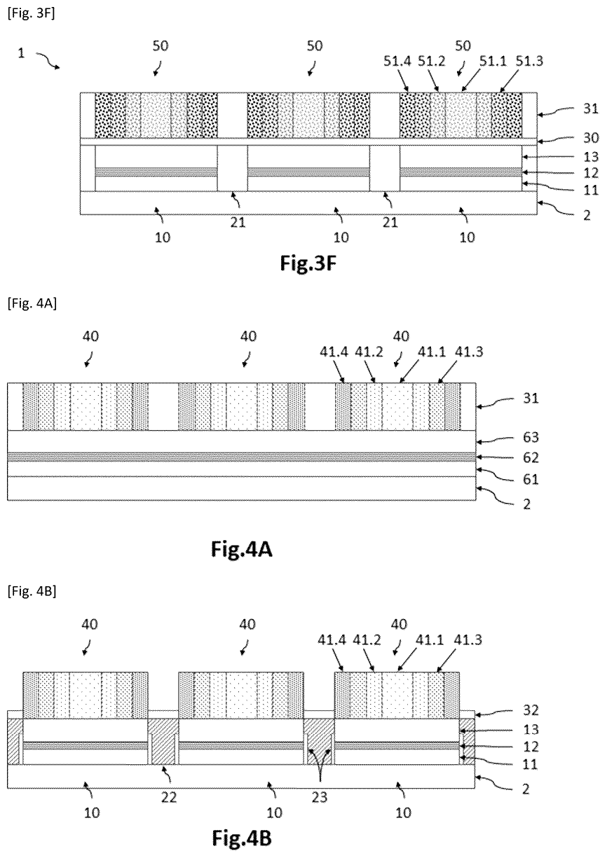

FIGS. 4A to 4C illustrate different steps of a variant of the manufacturing method of FIGS. 3A-3F, which is essentially distinguished from this by the fact that the step of pixelating the diodes 10 is carried out after the step of localized doping of the semiconductor portions 40 to be porosified.

FIG. 4A is similar to that of FIG. 3E, except that the diodes 10 have not yet been pixelated. Thus, a stack of semiconductor layers was transferred onto the control substrate 2. This stack comprises, starting from the control substrate 2, a P-doped semiconductor layer 61, an active layer 62, an N-doped semiconductor layer 63, and finally the continuous semiconductor layer 31. The latter comprises the locally doped semiconductor portions 40, intended to be porosified to form the optical components 50.

With reference to FIG. 4B, the locally doped semiconductor portions 40 and the diodes 50 are pixelated. For this purpose, a localized etching of the continuous semiconductor layer 31 and of the semiconductor layers 63, 62, 61, is performed so as to open through to the control substrate. The locally doped semiconductor portions 40 are thus made distinct from each other, as are the diodes 10.

Then the “N contacts” are made, by depositing a thin lateral layer 23, covering the lateral edges of the P-doped portions 11 and the active portions 12, then by depositing a metal material 22 that comes into contact with the lateral edge of the N-doped portions 13. A thin protective layer 32, which is inert during the electrochemical porosification step, can be deposited on the metal material 22, between the locally doped semiconductor portions 40, so as to protect it from any degradation during electrochemical porosification.

With reference to FIG. 4C, the optical components 50 are then produced by electrochemical porosification of the locally doped semiconductor portions 40. The electrical polarization thereof is carried out here by means of the N-doped portions 13, polarized via the “N contact” and the control substrate 2. It could also be carried out by means of the semiconductor junction, as in patent application FR3143850 A1 published on 21 Jun. 2024, with national registration number FR2213826, and filed on 19 Dec. 2022. The semiconductor portions 40, then porosified, therefore have the desired lateral variation Δ_{xy}p in the porosity rate p(x,y), and therefore the lateral variation Δ_{xy}ñ in the refractive index ñ(x,y). They therefore form the optical components 50.

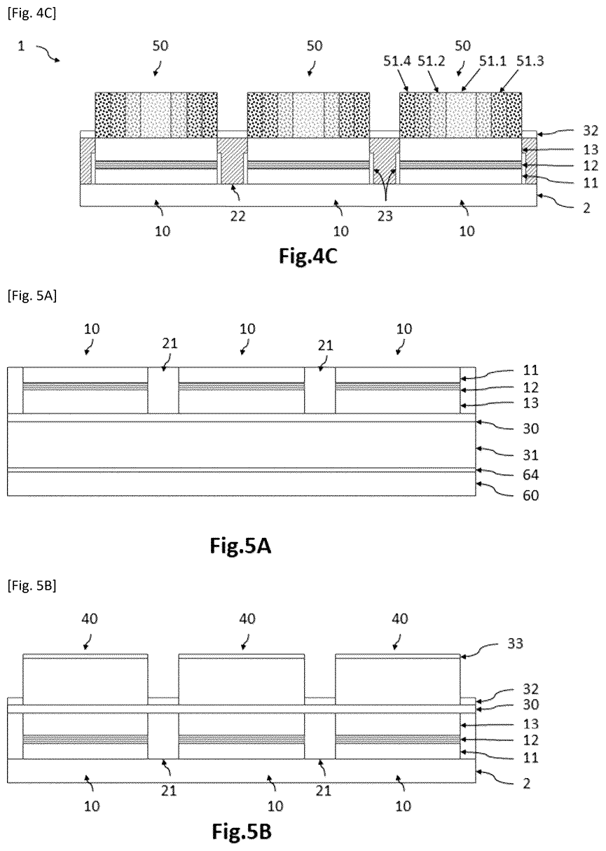

FIGS. 5A to 5C illustrate various steps of a method for manufacturing an optoelectronic device similar to that of FIG. 2. This method differs from that of FIGS. 3A-3F and 4A-4C essentially in that the lateral variation Δ_{xy}p in the porosity rate p(x,y) is obtained by modulation of the anodizing voltage Eₐ during the electrochemical porosification step.

With reference to FIG. 5A, a structure similar to the one shown in FIG. 3A is produced. It comprises a growth substrate 60, a thin protective semiconductor layer 64, the continuous semiconductor layer 31, a thin conductive layer 30, and the diode array 10. In this example, the polarization of the N-doped portions 13 is provided by the thin conductive layer 30. The diodes 10 are separated in pairs by an insulating separating material 21. However, alternatively, “N contacts” similar to those of FIG. 2 may be produced. The continuous semiconductor layer 31 is N-doped, with a doping level that allows for its subsequent porosification. The doping level is substantially homogeneous.

With reference to FIG. 5B, the diode array 10 is transferred onto the control substrate 2, and the growth substrate 60 is removed, so as to expose the upper face of the thin protective layer 64. The semiconductor portions 40 are then pixelated, by localized etching of layers 64 and 31. The semiconductor portions 40 then have a lateral edge with a free surface. Finally, their upper face is covered by a thin protective portion 33. A thin layer 32 may be deposited on the thin conductive layer 30, between the semiconductor portions 40, so as to protect it during the electrochemical porosification step.

With reference to FIG. 5C, the optical components 50 are then produced by electrochemical porosification of the semiconductor portions 40. As the doping level N_{D}y is substantially homogeneous, the lateral variation Δ_{xy}p in the porosity rate p is obtained by modulation of the anodizing voltage Eₐ, according to the approach described in patent application FR2406898, filed on 27 Jun. 2024.

For this purpose, the free surface of the lateral edge of the semiconductor portions 40 is brought into contact with the liquid electrolyte, and the structure is connected to the electric generator, here for example via the thin conductive layer 30. As before, the thin conductive layer 30 then forms a working electrode, here connected to the anode of the electric generator. A counter electrode (in this case a platinum wire or grid) is immersed in the electrolyte and connected to the cathode of the electric generator. The electric machine applies an electrical anodizing voltage Eₐ, the value of which is modulated over time. In other words, several values of electrical voltage Eₐ are applied so as to cause porosification in the semiconductor portions 40 starting from the lateral edge, and to obtain the desired lateral variation Δ_{xy}p in the porosity rate p.

For example, a first anodizing voltage Eₐ is applied for a first period of time, then a second anodizing voltage Eₐ for a second period of time. Thus, different values of the anodizing voltage Eₐ can be applied for different time periods. Indeed, the implementation of electrochemical porosification in several successive sequences, with different anodizing voltage values Eₐ, makes it possible to obtain the desired lateral variation Δ_{XY}p in the porosity rate p of the semiconductor portions 40 in the XY plane. It is then not necessary to have previously carried out a spatial distribution of the doping level, as in the examples of FIGS. 3A-3F and 4A-4C. For this purpose, a chart similar to that of FIG. 3D is used where, for an initial doping level, the modification of the value of the anodizing voltage E results in a different porosity rate.

It is possible to achieve any kind of spatial variation Δ_{xy}p in the porosity rate p. It is thus possible to obtain a core of the optical components 50 more porous than the lateral edge, or vice versa, with a monotonous variation (constant direction of variation) or not. It should be noted that the presence of thin protective portions 33 makes it possible to prevent the porosification of the semiconductor portions 40 from also occurring on the upper face. Thus, an essentially lateral variation in the porosity rate is obtained, with virtually no vertical variation. However, it is possible to have vertical variation in the porosity rate: for this purpose, the thin protective layer 64 (and therefore no thin protective portions 33) is not produced, so that the upper face of the semiconductor portions is also left free.

It should be noted that, here, the semiconductor portions 40 are polarized during the electrochemical porosification step by the same thin conductive layer 30. The optical components 50 then have the same lateral variation Δ_{xy}p in the porosity rate p. Alternatively, in the case where the diodes 10 are polarized by “N contacts” similar to those of FIG. 2, it is possible to polarize the semiconductor portions 40 independently during the electrochemical porosification step, either via the “N contacts”, or via the semiconductor junction. The optical components 50 can then have lateral variations Δ_{xy}p in the porosity rate p that differ from one optical component to the other.

FIGS. 6A to 6D illustrate different steps of another method for manufacturing an optoelectronic device similar to that shown in FIG. 2. In this example, the semiconductor portions 40, before the electrochemical porosification step, have a diode growth mesa shape 10.

With reference to FIG. 6A, a growth substrate 60 is produced covered by semiconductor portions 40 intended to be porosified. Thin protective portions 33 are made between the growth substrate 60 and the semiconductor portions 40. These are separate from each other in the XY plane. They have an N-type doping, with a homogeneous doping level within each semiconductor portion.

With reference to FIG. 6B, the diodes 10 are then produced from the free upper face of the semiconductor portions 40. A thin layer of nucleation mask (not shown) may be present and may cover the lateral edge of the semiconductor portions 40 and the free upper face of the growth substrate 60.

The diodes may be produced sequentially, one after the other (in diode groups), in the case where they have different optical transmission or reception properties. For this purpose, they have, for example, different indium levels in the quantum wells, enabling some to emit green light, others red light, and still others blue light.

Finally, the “N contacts” are made. For this purpose, the lateral edge of the N-doped portions 13, and preferably also that of the semiconductor portions 40, is made free. A metal material 22 then fills the interdiode space, and comes into contact with the lateral edge of the N-doped portions 13. A thin insulating layer 23 covers the lateral edge of the active portions 12 and the P-doped portions 11, to prevent electrical contact with the metal material 22.

With reference to FIG. 6C, the diode array 10 is transferred onto the control substrate 2. The growth substrate 60 is then removed. Thus, the upper face of the thin protective portions 33 is made free. The lateral edge of the semiconductor portions 40 is made free by localized etching of the metal material 22. This is kept between the diodes to ensure the polarization of the N-doped portions 13. Finally, preferably, a thin protective layer 32 is deposited on the metal material 22, between the semiconductor portions 40, so as to protect the latter (if necessary) during the electrochemical porosification step.

With reference to FIG. 6D, the optical components 50 are then produced by electrochemical porosification of the semiconductor portions 40. As these have a homogeneous N_{D} doping level, and a free lateral edge, porosification is carried out by modulating the anodizing voltage Eₐ. This step is similar or identical to the one described in connection with FIG. 5C.

Specific embodiments have been described. Different alternatives and modifications will become apparent to the person skilled in the art.

Thus, FIGS. 7A and 7B are schematic and partial views in cross-section (FIG. 7A) and in top view (FIG. 7B) of an optoelectronic device 1 according to one embodiment. This example shows that any type of lateral variation can be considered, in particular metasurface-type optical components 50 where areas with different porosity rates (and therefore different optical indices ñ) are adjacent in the XY plane.

Furthemore, FIG. 8 is a schematic and partial, cross-sectional view of an optoelectronic device 1 according to another embodiment. Here, the optoelectronic device comprises several optical components 50 stacked on top of one another, which may have different thicknesses. The stacked optical components 50 may have different lateral variations in the porosity rate and therefore in the refractive index.

In general, the optical components may be edged with a transparent or light-reflecting filler material. They may have dimensions that are substantially equal to, greater than or less than those of the diodes in the XY plane. The optical components may form converging, diverging, or specially shaped lenses for the transmitted light.

1. A method for manufacturing an optoelectronic device comprising: at least one light-emitting or light-receiving diode having a front face configured to transmit or receive a light radiation; at least one optical component for shaping the light radiation, disposed on the front face and covering the diode, and having a predefined lateral variation of a effective refractive index;
wherein the manufacturing method comprises the following steps:
providing the diode;
determining a lateral variation of a porosity rate of the optical component as function of the effective refractive index, from a predefined lateral variation of a target refractive index, of a semiconductor portion made of a crystalline material transparent to the light radiation and disposed on the front face and covering the diode;
producing the semiconductor portion to be porosified;
performing an electrochemical porosification of the semiconductor portion, such that it has the determined lateral variation in the porosity rate, the semiconductor portion thus porosified then forming the optical component.

2. The manufacturing method according to claim 1, wherein the determined lateral variation of the porosity rate has an amplitude greater than or equal to 5%.

3. The manufacturing method according to claim 1, wherein the optical component has a thickness, and wherein the porosity rate exhibits a variation along its thickness with an amplitude less than or equal to 4%.

4. The manufacturing method according to claim 1, wherein the semiconductor portion to be porosified has a flat upper face opposite the front face of the diode.

5. The manufacturing method according to claim 1, wherein:
during the step of producing the semiconductor portion to be porosified, it comprises several adjacent doped areas, having a doping level different from one doped area to the other;
during the electrochemical porosification step, the doped areas are porosified and have a different porosity rate from one doped area to the other.

6. The manufacturing method according to claim 5, wherein, during the step of producing the semiconductor portion to be porosified, each doped area has a homogeneous doping level laterally and vertically.

7. The manufacturing method according to claim 5, wherein:
the optoelectronic device comprises an array of diodes and several optical components formed from semiconductor portions to be porosified,
during the step of producing the semiconductor portions to be porosified, these are parts of a same continuous semiconductor layer extending over the diode array.

8. The manufacturing method according to claim 5, wherein, during the electrochemical porosification step, an electrical anodizing signal has a constant value over time until the lateral variation in the porosity rate is obtained.

9. The manufacturing method according to claim 1, wherein during the electrochemical porosification step, an intensity modulation of an electrical anodizing signal is performed, leading to obtaining the lateral variation in the porosity rate.

10. The manufacturing method according to claim 9, wherein, during the step of producing the semiconductor portion to be porosified, it has a laterally homogeneous doping level.

11. The manufacturing method according to claim 9, wherein, during the step of producing the semiconductor portion to be porosified, it has a free lateral edge.

12. The manufacturing method according to claim 9, wherein, during the step of producing the semiconductor portion to be porosified, it has an upper face covered by a thin protective portion made of a non-porosifiable material during the electrochemical porosification step.

13. The manufacturing method according to claim 1, wherein the semiconductor portion to be porosified is made of a material based on InP or (Al,In,Ga)N.

14. The manufacturing method according to claim 1, comprising the following steps:
producing the semiconductor portion to be porosified, in the form of a mesa, from a growth substrate;
producing the diode from the semiconductor portion to be porosified, in the form of a mesa;
transferring the diode and the semiconductor portion to be porosified onto a control substrate ;
performing electrochemical porosification of the semiconductor portion.

15. An optoelectronic device, comprising:
at least one light-emitting or light-receiving diode having a front face configured to transmit or receive light radiation;
at least one optical component for shaping the light radiation, disposed on the front face and covering the diode, and having a predefined lateral variation of an effective refractive index;
wherein the optical component is made of a transparent crystalline semiconductor material, and has a lateral variation of a porosity rate of the transparent crystalline material, which results in the predefined lateral variation of the effective refractive index.
